(19) United States
(12) Patent Application Publication
(10) Pub. No.: US 2009/0115530 A1
(43) Pub. Date: May 7, 2009

(54) Doherty-Amplifier System

(75) Inventor: Rainer Bott, Andechs (DE)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: Rohde & Schwarz GmbH & Co. KG, Munchen (DE)

(21) Appl. No.: 12/296,186

(22) PCT Filed: Nov. 12, 2007
(86) PCT No.: PCT/EP07/09781

§ 371 Date: Nov. 5, 2008

(30) Foreign Application Priority Data
Dec. 5, 2006 (DE) 10 2006 057 324.2

(51) Int. Cl. H03F 3/68

(52) U.S. Cl. 330/295

(57) ABSTRACT

A Doherty-amplifier system has several amplifier stages, of which the inputs are controlled via a control unit with different phase angles and/or signal amplitudes of an input signal. According to the invention, every output of every amplifier stage is connected directly to an antenna element, without the output signals from the amplifier stages being combined with one another before being supplied to the antenna elements.

The invention relates to a Doherty-amplifier system comprising a Doherty amplifier with a series-connected antenna structure.

Adaptive antenna systems or phased-array techniques are already known. See, for example, Sarkar et al. “Smart Antennas”, John Wiley & Sons, New Jersey, 2003. A one-dimensional or multidimensional antenna arrangement with so-called antenna arrays, consisting of individual antenna elements, wherein a signal to be transmitted is connected to the individual antenna elements by means of appropriate complex-value weighting (weighting in amplitude and phase), thereby achieving the required transmission beam with the resulting gain, is used with these arrangements in order to increase the transmitter-end antenna gain. Instead of using only one power amplifier for each element, these arrangements can also be realized by using a separate amplifier in each case, of which the respective signal amplitudes, and/or phases are adjusted to correspond with the required antenna beam.

Amplifier architectures designed to increase efficiency have been known for a considerable time. Among the methods, which are particularly suitable for signals with amplitude modulation, the Doherty architecture, as disclosed, for example in US 2006/0214732 A1, is particularly noteworthy. With this method, the individual amplifier paths are combined before connection to the antenna by means of appropriate couplers or combiners to form the desired sum signal, which is then supplied to the antenna.

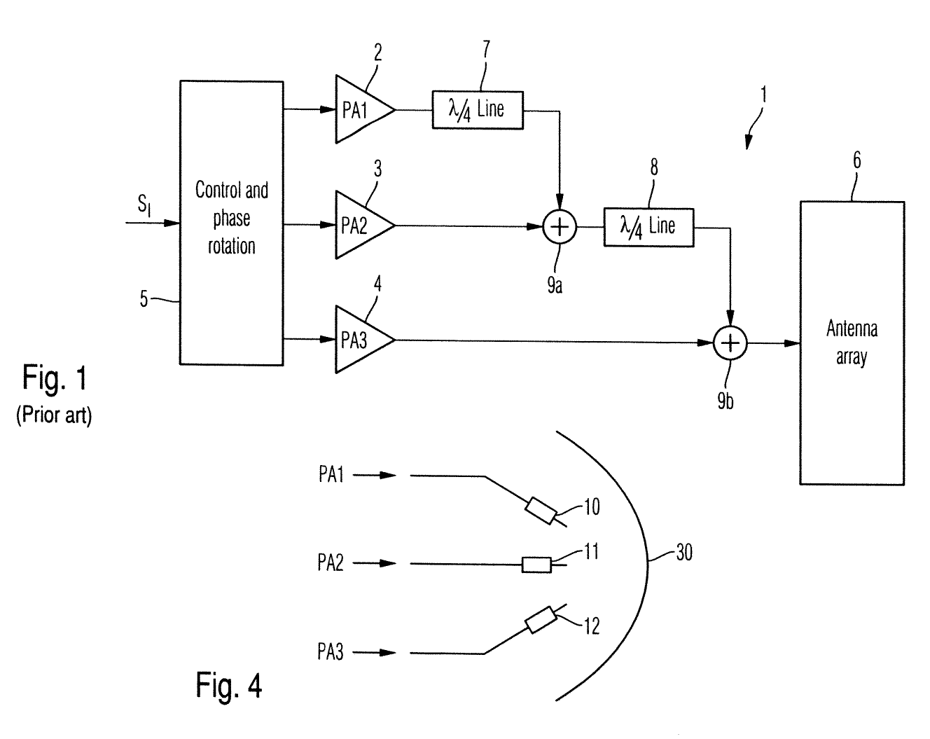

FIG. 1 shows a Doherty amplifier 1 according to the prior art. The individual amplifier stages 2, 3 and 4 are arranged in parallel. The input of each amplifier stage 2, 3, 4 is connected to a control unit 5, which supplies an input signal S_{I} with different phase angles and amplitudes to the individual inputs of the amplifier stages 2-4. The outputs of the amplifier stages 2-4 are connected to a common antenna 6. Only the output of a single amplifier stage 4 is connected directly to the antenna 6. The other outputs of the other amplifier stages 2 and 3 are connected to the antenna 6 via cascade-like phase displacers, which are formed in the exemplary embodiment as λ/4-lines 7 and 8. The output signals of the amplifier stages 2-4 are initially combined with one another in signal combiners 9a and 9b, before they are supplied to the antenna 6.

The disadvantage with this method is that the combiners either provide a relatively narrow bandwidth or are associated with a loss. Accordingly, when these amplifier architectures are connected to the adaptive antenna systems named above, the coupling methods described are disadvantageous.

The object of the present invention is to avoid these disadvantages and to achieve an enhanced Doherty system with improved efficiency.

This object is achieved by a Doherty system with the features of claim 1. The dependent claims specify advantageous further developments of the invention.

According to the invention, no signal combiners, which combine the output signals from the amplifier stages to form a sum signal before being supplied to the antenna, are provided at the outputs of the amplifier stages; on the contrary, the individual output signals from the amplifier stages are supplied directly to an array element of the overall antenna arrangement without the intermediate connection of signal combiners. In this context, one antenna element is preferably allocated to each amplifier stage. The combination of the output signals from the amplifier stages to provide the sum signal to be transmitted is then achieved by superposing the electromagnetic waves emitted from the respective antenna elements. In this manner, no signal combiner is required at the output of the amplifier stage, and the decoupling of the outputs of the amplifier stages is improved.

According to the invention, an antenna array, which principally can any structure, is subdivided into array elements (antenna elements) corresponding to the number of amplifiers to be operated in parallel. There is no a priori necessity for the number of individual antennas per array element to be identical. However, for reasons of simplicity and in order to achieve a similar radiation pattern, it is meaningful if the number of an antennas and the radiation pattern are identical or at least similar.

One amplifier is now connected directly to each of these array elements. The combination of the individual signals, which is normally implemented by means of appropriate combiners realized as a circuit within the overall amplifier, is implemented according to the invention by combining or superposing the electromagnetic waves emitted from the antennas. The disadvantages necessarily associated with combiners, such as losses or the relatively narrow bandwidth, are therefore avoided a priori.

The following section describes an exemplary embodiment of the invention with reference to the drawings. The drawings are as follows:

FIG. 1 shows a Doherty System according to the prior art;

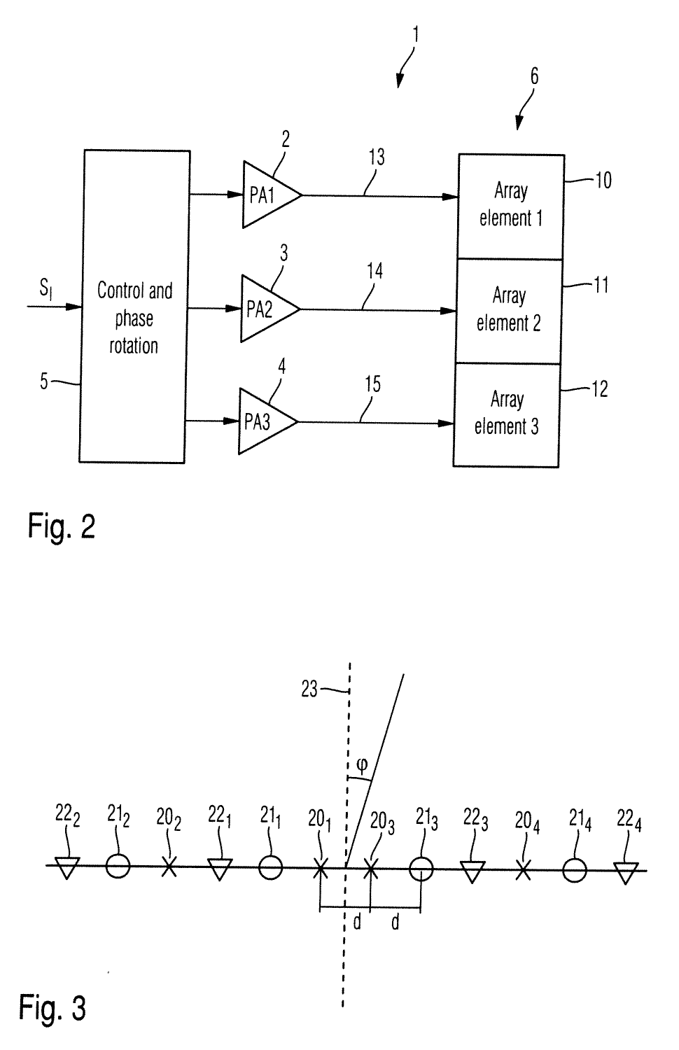

FIG. 2 shows an exemplary embodiment of the Doherty system according to the invention;

FIG. 3 shows an exemplary embodiment of an antenna array with ULVAs; and

FIG. 4 shows an exemplary embodiment of an antenna array with a parabolic reflector.

The method can be described in a particularly clear manner with reference to a Doherty-amplifier architecture and a one-dimensional ULVA (Uniform Linear Virtual Array). The system can be expanded to other antenna arrangements including multidimensional antenna arrangements as required and can be readily implemented. Accordingly, a ULVA can be converted into any required antenna arrangement, for example, by means of appropriate transformations, as described in Sarkar et al. “Smart Antennas”, John Wiley & Sons, New Jersey, 2003, Section 6, especially Section 6.2. The beam forming for a two-dimensional antenna arrangement is described, for example, in Ghavami, “Wideband Smart Antenna Theory Using Rectangular Array Structures”, IEEE Trans. On Signal Processing, Volume 50, No. 9, pages 2143 ff., September 2002.

A three-stage Doherty amplifier is used as a starting point for the explanation of the invention with reference to FIG. 2. Elements already described with reference to FIG. 1 are indicated with the same reference numbers, thereby simplifying the description. Here also, the Doherty amplifier consists of several amplifier stages 2, 3 and 4, of which the input is connected respectively to a control unit 5. Moreover, the control unit 5 controls the inputs of the amplifier stages 2-4 with different phase angles and/or signal amplitudes.

If the Doherty amplifier only needs to provide a low output power, only the first amplifier stage 2 is initially active. When the first amplifier stage 2 reaches saturation, its power is limited to a constant maximum value. Any further increase in power is achieved exclusively with the second amplifier stage 3. If the sum of the two powers of the two amplifier stages 2 and 3 is still insufficient, the second amplifier stage 3 is also limited to a constant maximum power when it reaches saturation, and the further increase in power is achieved by the third amplifier stage 4. Although three amplifier stages 2-4 are presented in the exemplary embodiment, the invention can, of course, also be realized with only two amplifier stages or with more than three amplifier stages.

By contrast with the Doherty system according to the prior art presented in FIG. 1, with the Doherty system according to the invention, every output of every amplifier stage 2, 3 and 4 is connected to a respectively-allocated antenna element 10, 11, 12, which is also referred to within the framework of the present application as an array element of the antenna array 6.

The individual output signals of the amplifier stages 2-4 are therefore not, as in the case of the prior art, initially subjected to different phase displacements and then combined with one another in signal combiners, but every output of every amplifier stage 2-4 is supplied directly to the antenna element 10-12 allocated to it. The signal combiners are therefore not required, and the decoupling of the outputs of the amplifier stages 2-4 is considerably improved.

Instead of coupling the amplifier outputs via λ/4-lines as realized according to the prior art, the individual amplifiers according to the invention are connected directly to the array elements. This is illustrated in FIG. 2 for three array elements. Expansion to include several parallel amplifiers, or also, reduction to only two amplifiers can be implemented in a simple manner. In this context, the beam forming is achieved by a corresponding complex-value weighting of the individual antenna signals.

FIG. 3 provides an example of how the individual antenna elements or respectively array elements 10, 11, 12 can be arranged within the overall antenna 6. In the exemplary embodiment presented in FIG. 3, each antenna element or respectively array element 10, 11 or 12 consists of several individual antennas, which are arranged in alternation with one another. For example, the first antenna element or array element 1 connected to the first amplifier stage 2 consists of the individual antennas 20₁, 20₂, 20₃ and 20₄. The second antenna element 11 or array element 2 connected to the second amplifier stage 3 consists of the individual antennas 21₁, 21₂, 21₃ and 21₄ and the third antenna element 12 or respectively the array element 3 connected to the third amplifier stage 4 consists of the individual antennas 221, 222, 223 and 224. In the exemplary embodiment illustrated in FIG. 3, the individual antennas are arranged starting from a central plane 23 in mirror symmetry on both sides of the central plane 23. However, a plurality of other one-dimensional or multidimensional arrangements is also possible.

As illustrated in FIG. 3, the ULVA is subdivided into N ULVA array elements. In FIG. 3, N=3. X denotes the antenna elements of the first array element; O denotes those of the second and ∇ those of the third array element. This subdivision corresponds to a spatial undersampling. Accordingly, in order to avoid ambiguities, spacing distances are required between the antenna elements with values smaller d/2·λ·N than. In this context, d is the spacing distance between two antenna elements; λ is the wavelength of the signal and N is the number of array elements. The use of respectively 2·L elements for every array element is advantageous but not compulsory. Accordingly, as already mentioned above, the radiation pattern of each of these array elements can be designed to be approximately identical.

For each of these three ULVA selected in this manner in the exemplary embodiment according to FIG. 3, the relationship for the field strengths in the remote field of the antennas is as follows:

$${E}_{1} ( t , ϕ ) = {S}_{1} ( t ) \cdot {\sum }_{l = 1}^{L} ( {W}_{1 , l} {e}^{j2π ( 3 \cdot 2 ( l - 1 ) + 1 ) \frac{d}{2 λ} sin ( ϕ )} + {W}_{1 , - l} {e}^{- j2π ( 3 \cdot 2 ( I - 1 ) + 1 ) \frac{d}{2 λ} sin ( ϕ )} )$$

$${E}_{2} ( t , ϕ ) = {S}_{2} ( t ) \cdot {\sum }_{l = 1}^{L} ( {W}_{2 , l} {e}^{j2π ( 3 \cdot 2 ( l - 1 ) + 3 ) \frac{d}{2 λ} sin ( ϕ )} + {W}_{2 , - l} {e}^{- j2π ( 3 \cdot 2 ( I - 1 ) + 3 ) \frac{d}{2 λ} sin ( ϕ )} )$$

$${E}_{3} ( ϕ ) = {S}_{3} ( t ) \cdot {\sum }_{l = 1}^{L} ( {W}_{3 , l} {e}^{j2π ( 3 \cdot 2 ( l - 1 ) + 5 ) \frac{d}{2 λ} sin ( ϕ )} + {W}_{3 , - l} {e}^{- j2π ( 3 \cdot 2 ( I - 1 ) + 5 ) \frac{d}{2 λ} sin ( ϕ )} )$$

W_{n,l} denotes the complex-value weighting for the antenna element 1 of the array element n. φ is the required direction of the beam of the resulting overall array. Sₙ (t) is the signal to be emitted via the array element n. In the preferred direction φ, the signal to be transmitted is then obtained in a simple manner as the sum of the signal components S₁ (t)+S₂ (t)+S₃ (t) without taking into consideration the antenna gain.

If the Doherty amplifier is driven at a low level, only the carrier amplifier PA1 is active and, accordingly, the signal is emitted only via the array element 1. If the carrier amplifier is operated to saturation, and the first peak amplifier PA2 is additionally active, the signals are transmitted according to the Doherty principle via the array elements 1 and 2. The signals are combined in the air by adding or respectively superposing the two partial waves. In the peak operating mode, the second peak amplifier PA3 is additionally active and the field strengths of the three arrays are superposed.

When operating at average power, the carrier amplifier PA1 supplies a constant amplitude. An amplitude modulation of the transmission signal is implemented by variation of the transmission amplitude of the peak amplifier PA2 and the resulting superposition of the field strengths according to the beam forming. The same applies for operation at high-power, during which the PA3 is active.

Moreover, this arrangement can also be used with directional antennas, in which the directional effect is achieved by mechanical measures. Accordingly, with parabolic antennas n feeders are used, and accordingly, the combination is implemented by adding the signals from the individual feeders.

Instead of mechanical measures, the directional effect can also be achieved by varying the signal-delay times through dielectrics. Antennas of this kind are sometimes referred to as Luneberg antennas.

In particular, methods are proposed for operating amplifier architectures with several individual amplifiers in an antenna array, wherein this array is subdivided into array elements, and wherein each amplifier is driven directly to an array element, and the signals from the individual amplifiers are combined to form the actually-transmitted signal by superposing the electromagnetic waves emitted from the respective array element.

By preference, a different signal is transmitted from each amplifier via the connected array element, and the actual transmission signal is formed by combining the electromagnetic waves of the array elements. However, each amplifier can also transmit the same signal via the connected array element.

The antenna array can implement a beam forming by corresponding wiring of the individual antennas of the array elements. The desired radiation pattern of the sum signal is then obtained from the result. The antenna array can provide any required multidimensional structure, and the beam forming can be implemented through appropriate complex-value weighting (amplitude weighting and phase rotation). In particular, the antenna array can be modeled as a so-called ULVA (Uniform Linear Virtual Array), which can be one-dimensional or multidimensional, and the real array structure can be obtained through appropriate transformation from/to the ULVA.

As an alternative, a method is proposed for operating amplifier architectures with several individual amplifiers in an antenna array, wherein, instead of an antenna array with individual antennas, which implement its beam forming through corresponding weighting of the feeder signal, an antenna arrangement is used, wherein the beam forming is achieved through the mechanical structure of the antenna, and this antenna is then connected by corresponding feeding through the different amplifiers.

In this context, the antenna arrangement can be implemented from different individual antennas with beam forming through mechanical measures, which point in the required direction of the resulting beam, wherein each individual antenna is fed from one of the amplifiers.

The antenna can also be a parabolic antenna and the feeding can be realized through different feeders, the number of which corresponds to that of the amplifier stages. This is illustrated in FIG. 4, which shows a parabolic reflector 30. The antenna elements 10-12 are arranged as feeders to different positions of the parabolic mirror 30.

Instead of the mechanical structure, beam forming can also be implemented through delay times in dielectrics. In this context, one antenna element can be designed as a Luneberg antenna.

The invention is not restricted to the exemplary embodiment presented and can also be used for array elements configured in a different manner.

1. Doherty-amplifier system comprising several amplifier stages having respective outputs and inputs with the inputs controlled via a control unit with different phase angles and/or amplitudes of an input signal
wherein
every output of every amplifier stage is connected directly to an antenna element without the output signals from the amplifier stages being combined with one another before being supplied to the antenna elements.

2. Doherty-amplifier system according to claim 1,
wherein
the output signals of the amplifier stages are combined to form a sum signal to be transmitted by superposing the electromagnetic waves emitted from the respective antenna element.

3. Doherty-amplifier system according to claim 2,
wherein
each antenna element comprises several individual antennas and each antenna element is provided through a corresponding wiring of the individual antennas with a beam forming of the radiation pattern such that a predetermined beam forming of the radiation pattern of a superposed sum signal is obtained.

4. Doherty-amplifier system according to claim 3,
wherein each
antenna element provides a given one-dimensional or multidimensional structure comprising individual antennas and the beam forming results from a amplitude weighting and weighting of the phase shift, of the individual antennas.

5. Doherty-amplifier system according to claim 4,
wherein each antenna element is modeled as a one-dimensional multidimensional Uniform Linear Virtual Array (ULVA), and the real structure results from an appropriate transformation.

6. Doherty-amplifier system according to
claim 1, wherein
beam forming is realized through the mechanical structure of the antenna elements, and said antenna elements are connected via different feed lines with different attenuation and/or phase displacement to the amplifier stages.

7. Doherty-amplifier system according to
claim 1, comprising
a parabolic reflector whereas the antenna elements radiate into the parabolic reflector at different positions.

8. Doherty-amplifier system according to
claim 1, wherein
at least one antenna element is a Luneberg antenna.
